(19) United States
(12) Patent Application Publication
(10) Pub. No.: US 2002/0140081 A1
(43) Pub. Date: Oct. 3, 2002

(54) Highly integrated multi-layer circuit module having ceramic substrates with embedded passive devices

(76) Inventors: Young-Huang Chou, Yi-Lan Hsien (TW); Jyh-Wen Sheen, Hsinchu (TW); Wen-Jen Tseng, Kaohsiung (TW); Chin-Li Wang, Hsinchu (TW); Jian-Hong Chen, Shu-Lin City (TW); Ching-Wen Tang, Nan-Tou City (TW)

Correspondence Address: SUPREME PATENT SERVICES, POST OFFICE BOX 3318, Saratoga, CA, 95070, US

(21) Appl. No.: 09/823,844

(22) Filed: Mar. 30, 2001

Related U.S. Application Data
(60) Provisional application No. 60/254,219, filed on Dec. 7, 2000.

(51) Int. Cl. H01L 21/44; H01L 23/04; H01L 29/40; H01L 23/06; H01L 21/48

(52) U.S. Cl. 257/700; 257/698; 257/703; 438/125; 257/758; 438/118; 438/622; 257/774; 438/629; 257/924

(57) ABSTRACT

A plurality of ceramic substrates are used to manufacture and integrate a highly integrated multi-layer circuit module. Integrated circuit devices are mounted on one or both surfaces of the circuit module whose multi-layer structure is divided into three types of integration regions including inter-connection integration regions, basic passive device integration regions and high frequency passive device integration regions. Connection layers are formed in the inter-connection integration regions for connecting integrated circuits. Basic passive device integration regions include capacitor, resistor and inductor layers. Filters, couplers and baluns are fabricated in the high frequency passive device integration regions. Shielding ground planes are provided for the isolation of devices to prevent electromagnetic interference. Standard input and output contacts are formed on the bottom surface so that the circuit module can be used as a modularized device.

### FIELD OF THE INVENTION

The present invention generally relates to a multi-layer circuit module, and more specifically to a highly integrated multi-layer circuit module manufactured with multiple ceramic substrates and embedded passive devices and the method of designing and integrating the same.

### BACKGROUND OF THE INVENTION

FIG. 1 illustrates a circuit structure of a modern wireless communication system. The basic components in the system include an RF frond end 101, a modulation and de-modulation module 102, a base band control circuit 103 and a flash memory module 104. Each of these basic components has its own integrated circuit in combination with associated peripheral devices to provide the necessary functions that satisfy the requirements specified for the system. The system also comprises a high frequency filter 108, baluns 105, a switching diode 106, a power amplifier 107 and an antenna 109.

The conventional approach to designing such a system generally partitions the system into several sub-modules. Each sub-module is designed and tested individually. The sub-modules are then integrated together into a whole system as shown in FIG. 2. The wireless communication system of FIG. 2 comprises an antenna 201, a filter 202, baluns 203, a high frequency switch 204, a transistor 205, a flash memory module 206, peripheral passive devices 207, a base frequency integrated circuit device 208, and a radio frequency integrated circuit device 209. The peripheral passive devices include capacitors, resistors and inductors.

Because of the complexity involved in the modern communication system, the conventional approach of design and development is very complicated and difficult. In particular, many changes often have to be made to the sub-modules during the integration stage in order to meet the specification and functional requirements of a product. Furthermore, each sub-module may also require additional modification to optimize integration of the system. Therefore, both development cost and time are increased during the integration.

In addition to the drawback of the conventional approach to designing and developing a product described above, the electronic product in the state of the art is becoming more and more compact with more and more functions. The complexity in the product has also made the conventional approach obsolete. A recent technology has been developed for integrating electronic circuits by manufacturing multi-layer structures with stacked FR4 substrates as shown in FIG. 3.

As can be seen from the cross-sectional view in FIG. 3, the top integration layer 302 includes an integrated circuit device 306, passive devices 307 and an active device 308. The bottom integration layer includes passive devices 309 and 311, an integrated circuit device 310, and an active device 312. Inter-connection layers 303 provide signal connection paths between various devices, and shielding ground planes 304 provide isolation of devices and signal connection paths to avoid electromagnetic interference. An antenna 301 is also mounted on the top surface.

As illustrated in FIG. 3, the integrated circuit components and their associated peripheral devices are installed on top and bottom layers of the multi-layer structure. The signal paths for connecting circuits and devices are routed through inter layers of the structure to increase the flexibility of designing the system. However, this integration approach becomes less feasible when circuit module miniaturization is necessary. Unless the number of peripheral devices is reduced by having improved circuits from circuit designers, it is not possible to reduce a product size by this approach.

In the circuit structure of a modern communication system, passive devices occupy most of the areas in the system. These passive devices include capacitors, resistors, inductors, filters, baluns, couplers, antennas and others. In terms of device count, the number of passive devices represents approximately 95% of the total number of the devices. Nevertheless, they occupy about 80% of the total volume of the system. In addition, the coupling networks required to integrate the sub-modules further increase the areas and volumes occupied by these passive devices considerably.

As described above, the conventional approach of integrating a multi-layer circuit structure only relies on embedded signal paths to increase the compactness of the circuit module. It does not save areas or volumes occupied by the passive devices effectively. Furthermore, in a wireless system an antenna includes an external device which requires careful design consideration. The relative layout of the circuit devices and the antenna in the system also needs to be taken into account to achieve the desired characteristics. Consequently, additional areas are usually wasted because of the layout consideration.

### SUMMARY OF THE INVENTION

This invention has been made to overcome the above mentioned drawbacks of integrating a conventional multi-layer circuit structure. The primary object is to provide an improved structure of a multi-layer circuit module. Another object is to provide a method of planning and designing the structure and arrangement of active devices, basic passive devices, high frequency passive devices and shielding ground planes in the multi-layer circuit module. It is also an object of the invention to provide a method of integrating the various devices together for the multi-layer circuit module.

Accordingly, the multi-layer circuit module of this invention comprises a plurality of ceramic substrates. Active integrated circuit devices are mounted on one or both of the top and bottom surfaces of the circuit module. The ceramic substrates of this invention have sufficiently high Q-factor for the frequency band used in current wireless communication. The high frequency response of the substrates is very good. Passive devices can be fabricated directly in the multiple ceramic substrates to reduce the number of devices on the top and bottom surfaces. The size of the multi-layer circuit module is thus greatly reduced.

In the present invention, the multi-layer circuit module is divided into several integration regions according to the passive devices used in the circuit module. The integration regions include inter-connection integration regions, basic passive device integration regions and high frequency passive device integration regions. Connection layers in the inter-connection integration regions provide the interconnection between the integrated circuit devices mounted on the surfaces of the circuit module. Capacitors, resistors and inductors are fabricated in their respective layers comprised in the basic passive device integration regions. High frequency passive devices such as filters, couplers, baluns and antennas are formed in the high frequency passive device integration regions.

The connection between the integrated circuit devices on the surfaces and the connection layers are accomplished by filled vias. The connection layers are placed next to the top or bottom surface to avoid the difficulty in interposing passive devices among large number of filled vias. The basic passive device integration regions are placed next to the connection layers. Within the basic passive device integration regions are capacitor layers, resistor layers and inductor layers. The capacitor layers are placed closer to the connection layers because the integrated circuit devices usually require a large number of capacitors. Following the basic passive device integration regions are the high frequency passive device integration regions.

In order to avoid electromagnetic interference, a ground plane is used to shield and isolate the surface layer or a connection layer from the internal integration layers. Capacitor layers are also embedded between two shielding ground planes to isolate the capacitors from other integration layers. Filled vias connected to ground is also used to effectively isolate an installed capacitor and avoid mutual coupling and change in the characteristics of the capacitor. High frequency passive devices have less number of input and output pins but require large continuous space. They are positioned in the middle layers of a multi-layer circuit module with careful arrangement to preserve the desired characteristics of each passive device. Shielding ground planes and filled vias connected to ground are also used to avoid mutual coupling.

In one embodiment of the invention, active integrated circuit devices are mounted on both top and bottom surfaces of the circuit module. As described above, the high frequency passive devices are designed and integrated in the middle layers, followed by basic passive device layers and connection layers on both sides. The bottom surface is designed with input and output contacts. The invention uses ball grid contacts that comply with the specification of standard inputs and outputs of a modularized device.

In another embodiment of the invention, active integrated circuit devices are mounted only on the top surface of the circuit module. Because the bottom surface is designed with input and output contacts, the complete grounding of the shielding ground plane is destroyed. In this embodiment, the basic passive device layers are divided into two parts. The capacitor and resistor layers are placed on one side of the high frequency passive device layers and inductor layers are placed on the other side.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 shows the block diagram of the basic structure of a wireless communication system.

FIG. 2 shows a multi-layer circuit structure of a wireless communication system integrated with conventional technology.

FIG. 3 shows a cross-sectional view of a multi-layer circuit module having both active and passive devices mounted on both surfaces of the circuit module integrated using technology known in the art.

FIG. 4 shows a cross-sectional view of an embodiment of the multi-layer circuit module designed and integrated by mounting active devices on top and bottom surfaces and embedding capacitors, resistors, inductors and high frequency passive devices in the ceramic substrates according to this invention.

FIGS. 5(a)-5(c) show the connection between devices mounted on the top surface, the inter-connection integration region and the basic passive device integration region as well as shielding ground planes of the multi-layer circuit module according to this invention.

FIGS. 6(a) and 6(b) show the connection layers and the shielding ground planes in the inter-connection integration region for the devices on the top surface of the multi-layer circuit module according to this invention.

FIG. 7 shows the inductor integration layers having inductors formed by spiral lines and high frequency short circuits and isolation circuits formed by transmission lines according to this invention.

FIG. 8 shows the cross-sectional view of another embodiment of the multi-layer circuit module having circuit devices mounted only on one surface according to this invention.

FIGS. 9(a) and 9(c) show a multi-layer bluetooth communication module designed and integrated according to the invention.

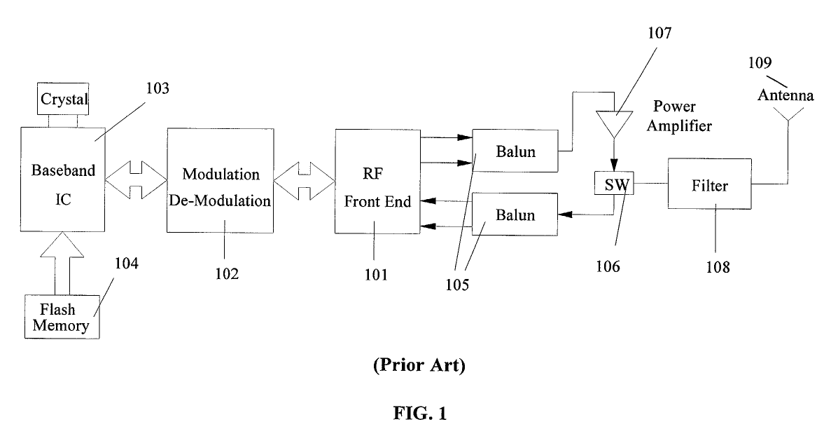

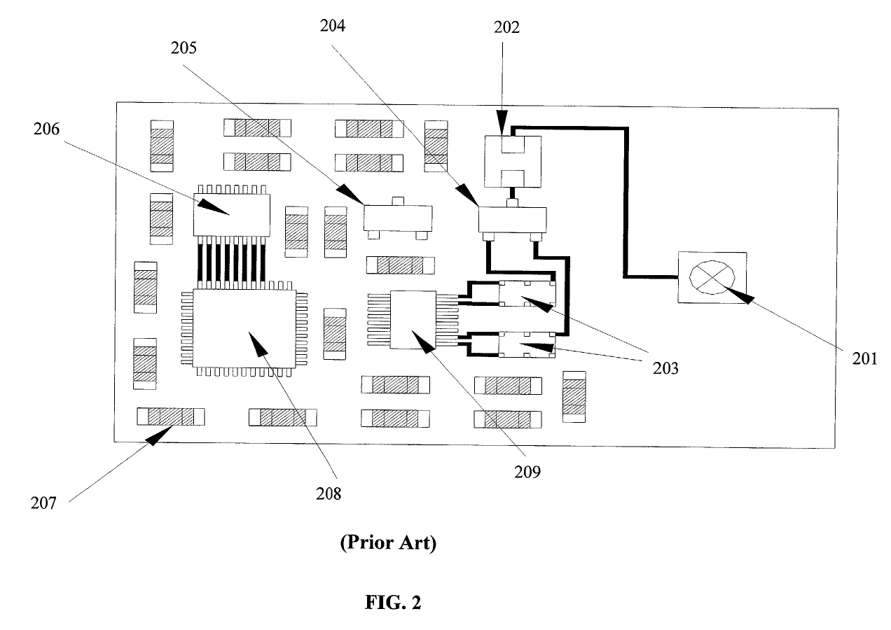

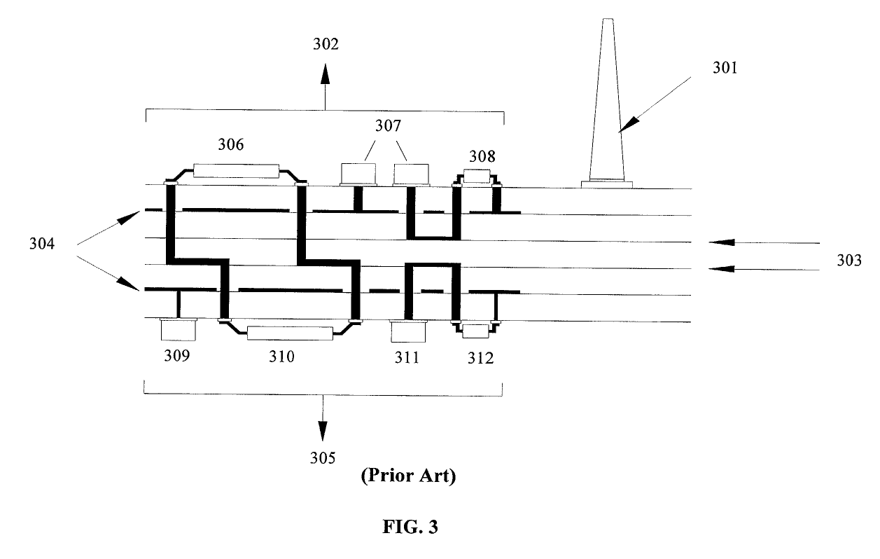

### DETAILED DESCRIPTION OF THE INVENTION

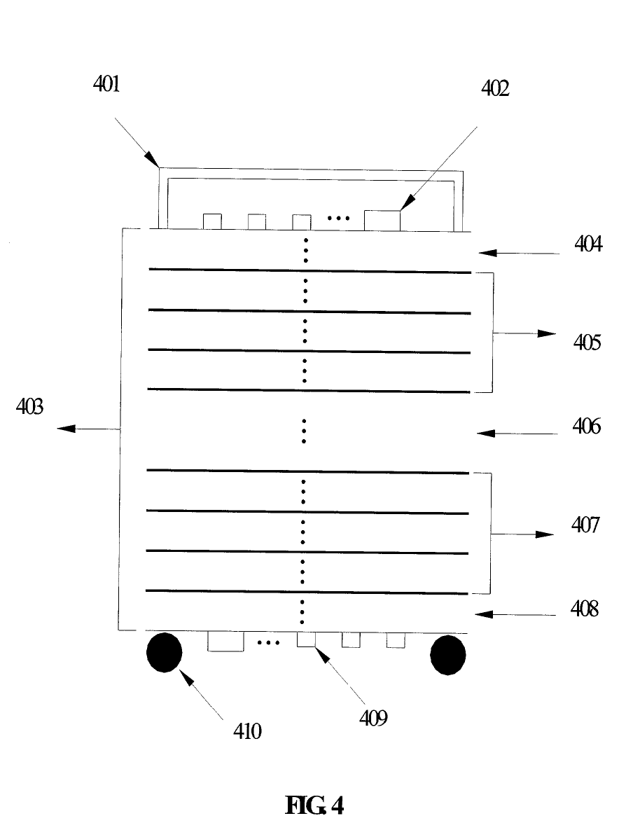

FIG. 4 illustrates an embodiment of a multi-layer circuit module designed and integrated according to the present invention. The structure of the circuit module comprises multi-layer ceramic substrates formed by low temperature co-fired ceramic technology. The multi-layer structure is divided into several integration regions according to the passive devices used in the actual circuit.

These integration regions including inter-connection integration regions, basic passive device integration regions and high frequency passive device integration regions. Inter-connection integration regions contains connection layers. Basic passive device integration regions further comprise capacitor layers, resistor layers and inductor layers. High frequency passive device integration regions are reserved for high frequency devices such as filters, baluns, couplers and antennas.

The connection of devices or signal lines between different layers is accomplished by filled vias with shielding ground to isolate signals and avoid interference. Active devices and other devices that can not be embedded in the multilayer structure are installed on the surfaces of top and bottom layers. Inputs and outputs are implemented by means of ball grid contacts formed on the bottom layer of the circuit module which complies with the standard specification of modularized devices.

The structure of the multi-layer circuit module as shown in FIG. 4 comprises a plurality of stacked ceramic substrates 403. Circuit devices are mounted on both top and bottom surfaces of the circuit module. A top metal shield 401 covers the devices 402 mounted on the top surface. Near the top surface is an upper inter-connection integration region having connection layers 404. A number of basic passive device layers 405 constitute an upper basic passive device integration region. In the middle is a high frequency passive device integration region that comprises high frequency passive device layers 406. Below the high frequency passive device integration region is a lower basic passive device integration region formed by several basic passive device layers 407. A lower inter-connection integration region consists of connection layers 408 is placed below the lower basic passive device integration region. Circuit devices 409 are mounted on the lower surface. Inputs and outputs are formed by ball grid contacts 410. The planning and design of the integration regions are described in the following:

1. Installation of Devices on Surface Layers

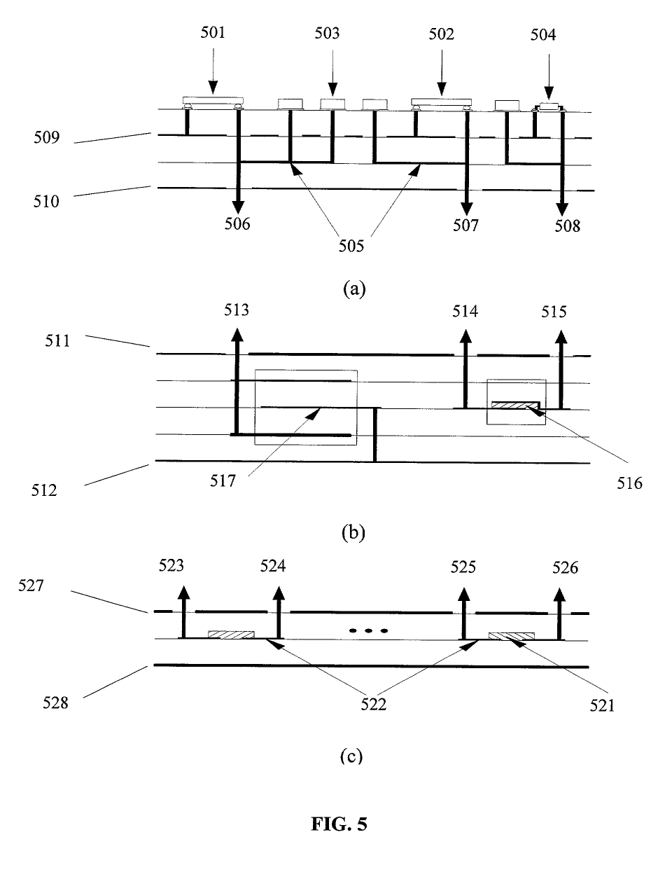

The devices to be installed on the surfaces of top and bottom layers are laid out as much regular and aligned as possible to save space without the consideration of how the devices are connected. Only high frequency signals are routed between devices. The control signals and DC power supply lines are provided by the connection layers next to the surface layers through filled vias. The number of connection layers depends on the complexity of the circuit. By having the connection layers directly adjacent to the surface layers, the integration is more flexible because the connection can be made to the devices on the surface side or the passive devices on the other side as in the example shown in FIG. 5.

With reference to FIG. 5, the example shows that the top surface of the circuit module has integrated circuit devices 501 and 502, external passive devices 503 and active devices 504 mounted thereon. The connection layer has connection lines 505 for connecting the devices. Filled vias 506, 507 and 508 are formed downwards for connecting the connection layer to the passive devices in the basic passive device integration region. Shielding ground planes 509 and 510 provide ground for devices and isolation for avoiding electromagnetic interference as shown in FIG. 5(a).

Shielding ground planes 511 and 512 isolate an embedded printed capacitor 516 and an embedded stacked capacitor 517 as shown in FIG. 5(b). Filled vias 513, 514 and 515 are formed upwards for connecting the passive devices to the connection layer. Connection lines 522 and filled vias 523, 524, 525, and 526 connect embedded resistors 521 to the connection layers as shown in FIG. 5(c). Shielding ground planes 527 and 528 isolate the embedded resistors 521.

In general, integrated circuit devices installed on the surface layers have may pins. A large number of filled vias are required to connect the integrated circuit devices along with their associated peripheral devices. Therefore, other passive device integration layers should not be located between the connection layers and the surface layers to avoid the difficulty in designing other passive devices with the large number of filled vias interposed in between. Furthermore, the input and output signals that have to be connected to the ball grid contacts on the bottom layer are arranged in the periphery of the module for easy connection to the bottom layer. Thus, the design and integration of these internal passive devices are not affected by these signal lines.

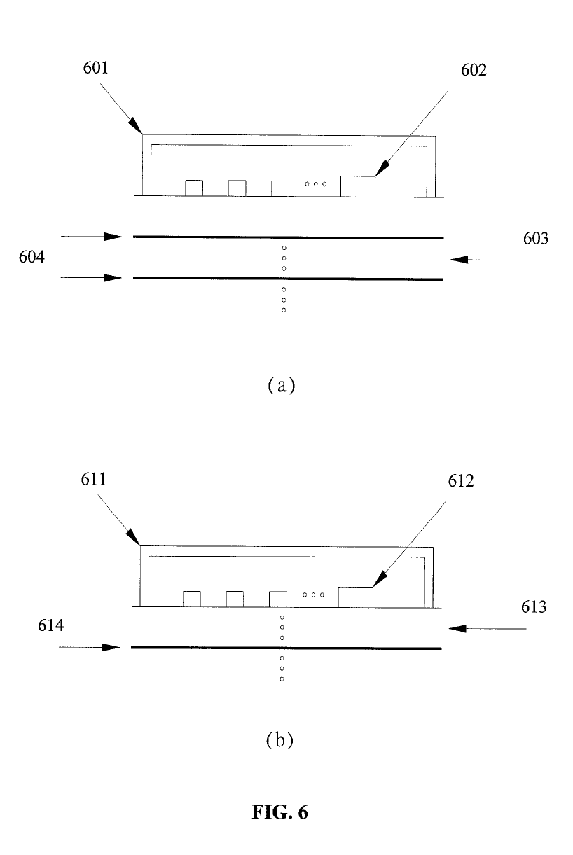

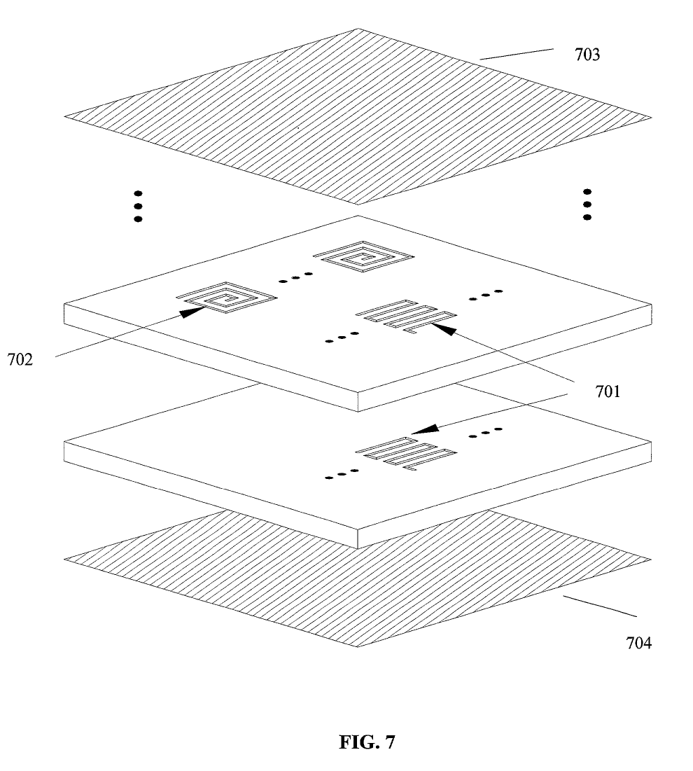

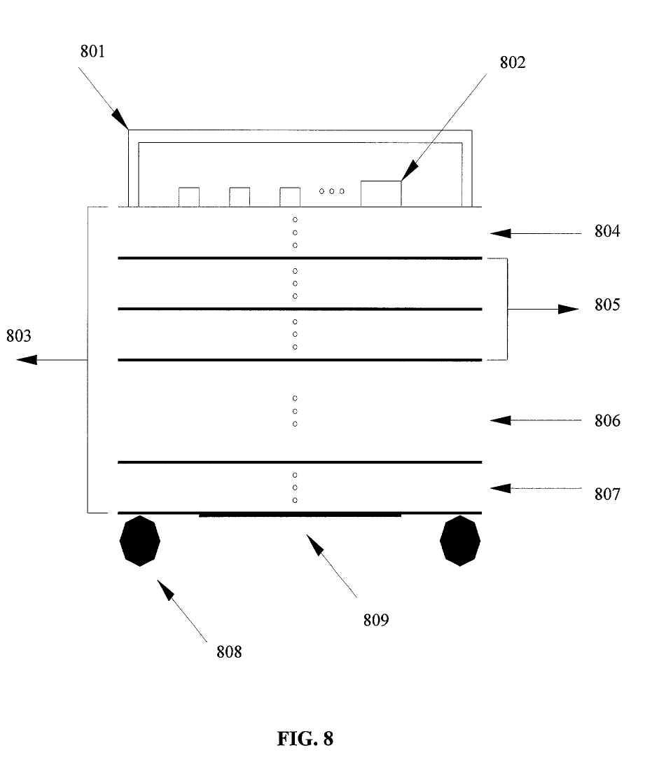

To avoid electromagnetic interference, a ground layer is used to shield and isolate a surface layer or a connection layer from the internal integration regions as shown in FIG. 6(a). A metal shield 601 covers the devices 602 mounted on the surface. Shielding ground planes 604 isolate the inter-connection integration region 603. In some case, the shielding ground plane for isolating a surface layer may not be necessary. As shown in FIG. 6(b), the inter-connection integration region 613 directly adjacent to the surface layer is isolated by a shielding ground plane 614. The devices 612 are mounted on the surface layer and covered by a metal shield 611. There is no shielding ground plane between the surface layer and the inter-connection integration region 613. For a radio frequency circuit, the position of the shielding ground has to be determined according to the width of a high frequency 50 ohm line on the surface layer in order to be in compliance with the requirements in the manufacturing process.

2. Basic Passive Device Integration Regions

The devices in the basic passive device integration regions are capacitors, inductors and resistors. Each device type has its own integration layers. The location of the integration region is determined by the number of devices and the complexity of connection. In general, the number of capacitors in a circuit is larger than that of other devices. In addition, most of the signal lines in the connection layers have capacitors integrated with them. Therefore, it is very helpful to the integration by arranging capacitor layers after connection layers.

According to the manufacturing process, capacitors can be either stacked or printed as shown in FIG. 5(b). Stacked capacitors are used for fabricating smaller capacitance. They are more precise but require more layers to manufacture. Printed capacitors can have larger capacitance. They require less layers to manufacture but have larger inaccuracies. In a matured process, the value of capacitance of a printed capacitor can be controlled to within 20% accuracy.

Due to the thickness consideration of a circuit module, it may not be possible to manufacture a stacked capacitor with too many layers. Consequently, the area has to be increased in order to fabricate an equivalent stacked capacitor with less layers. The increased area contradicts the goal of product miniaturization. In practice, the capacitance realized by a stacked capacitor with three metal layers and a common ceramic material having εᵣ=7.8 should not be greater than 10 pf.

In order to be isolated from other integration regions, capacitor layers are embedded between two shielding ground planes as shown in FIG. 5(b). Because of the effect of stray capacitance, capacitor layers are more suitable for the realization of grounding capacitors. In general, the number of grounding capacitors in a circuit structure is higher than others. Therefore, the use of capacitor layers does not present more difficulty in designing the circuit module. In the design, filled vias connected to ground can be used to effectively isolate each installed capacitor to avoid any mutual coupling and change in the characteristics of a capacitor.

Because the number of resistors is only second to the number of capacitors, the resistor layer is arranged after the capacitor layer. A resistor can be fabricated by printing a resistive type material between two electrical nodes as shown in FIG. 5(c). The last basic passive device integration layer is the inductor layer because inductors are least used in a circuit. An inductor is manufactured by means of a spiral line 702 in a defined layer as shown in FIG. 7 to achieve a desired equivalent inductance value. As can also be seen, the induction layers are shielded by two shielding ground planes 703 and 704.

In addition to the inductors, high frequency isolation circuits or high frequency short circuits are also designed with transmission lines 701 in the inductor layers. The value of desired inductance determines how long the transmission line should be. The operating frequency also determines the length of the transmission line for a high frequency isolation or short circuit. The total number of inductor layers is dependent of these two important factors.

The number of inductor layers should be carefully controlled. It must be in compliance with the size and thickness of the circuit module so that optimal integration of the system can be achieved. Each spiral line can also be isolated effectively by filled vias connected to ground. When the number of inductors used in the circuit is not many and the inductance values are small, it may also be possible to design microstripes on the surface layers directly if there is space available. This approach may eliminate the need of the inductor layers.

3. High Frequency Passive Device Integration Regions

High frequency passive devices include filters, couplers, baluns, and antennas. These devices have less number of input and output pins but require large continuous space for designing the main circuit. Therefore, it is better to arrange them in the middle layers of a circuit module. Each device may not be used in all layers. In designing each device, the space used is isolated by means of shielding ground planes or filled vias connected to ground to avoid mutual coupling and change in characteristics.

In addition to the basic theory of designing the high frequency passive devices, the total number of integration layers has to be well planned according to the size of the circuit module. The arrangement of relative locations among the devices should be made with the premise of preserving the characteristics of each device in order to achieve most efficient use of the available space with least interference.

Within each integration layer, the relative locations among the devices are more flexible. Each designer can make appropriate arrangement according to a particular circuit system. For a circuit module having circuit devices on both top and bottom surfaces, the high frequency passive device integration layers are arranged in the middle of the circuit module. Basic passive device integration layers and connection layers are formed both above and below the middle high frequency passive device integration layers to integrate and connect the circuit devices installed on the top and lower surfaces.

According to this invention, the capacitor layers in the basic passive device integration regions must be adjacent to the connection layers. The order of resistor layers and inductor layers can be more flexible according to the need of the particular circuit. It should be noted that the order of high frequency passive device integration layers, basic passive device integration layers and connection layers must be arranged accordingly to reduce the design difficulty and complexity.

For another embodiment of this invention, a circuit module has only one surface installed with circuit devices and the bottom surface is designed with input and output contacts. The complete grounding of the shielding ground plane used to isolate the high frequency passive device integration layers is destroyed by the input and output contacts. To overcome this problem, the basic passive device integration layers can be divided into two parts. The capacitor layers and resistor layers stay on one side of the high frequency passive device integration layers but the inductor layers are moved to the other side as shown in FIG. 8.

The structure of the multi-layer circuit module as shown in FIG. 8 comprises a plurality of stacked ceramic substrates 803. Circuit devices are mounted only on the top surface of the circuit module. A top metal shield 801 covers the devices 802 mounted on the top surface. Near the top surface is an inter-connection integration region having a connection layer 804. An upper basic passive device integration region 805 comprises capacitor and resistor layers. The high frequency passive device integration region 806 is placed below the capacitor and resistor layers. Below the high frequency passive device integration region 806 is a lower basic passive device integration region which comprises conductor layers. Inputs and outputs are formed by ball grid contacts 808 on the bottom surface. A ground plane 809 is also formed on the bottom surface.

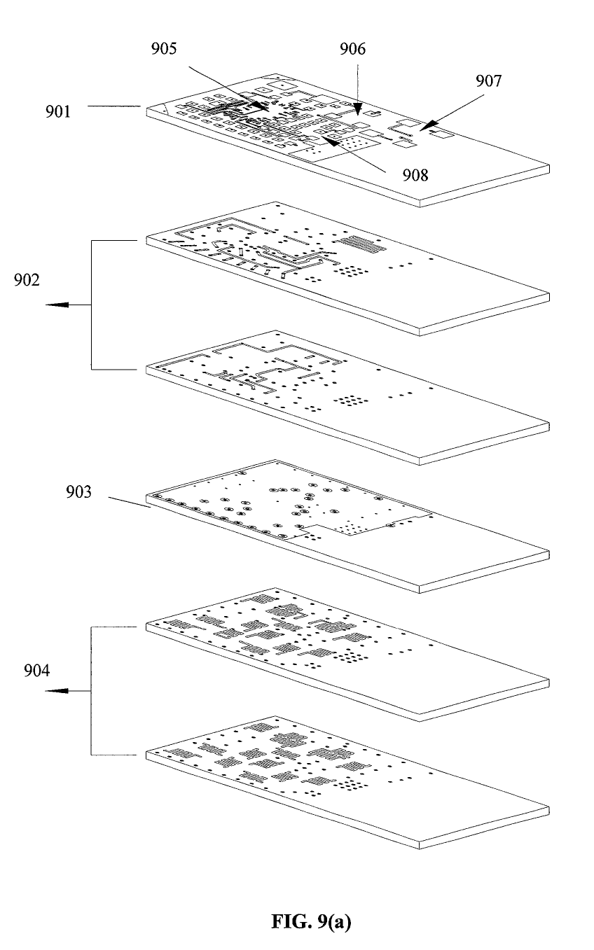

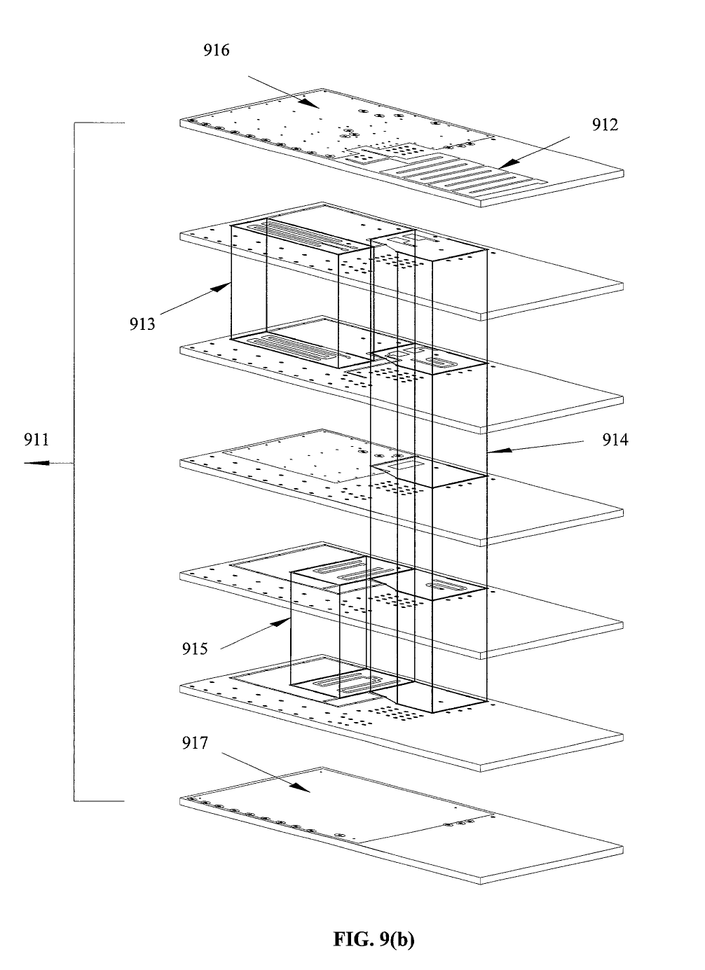

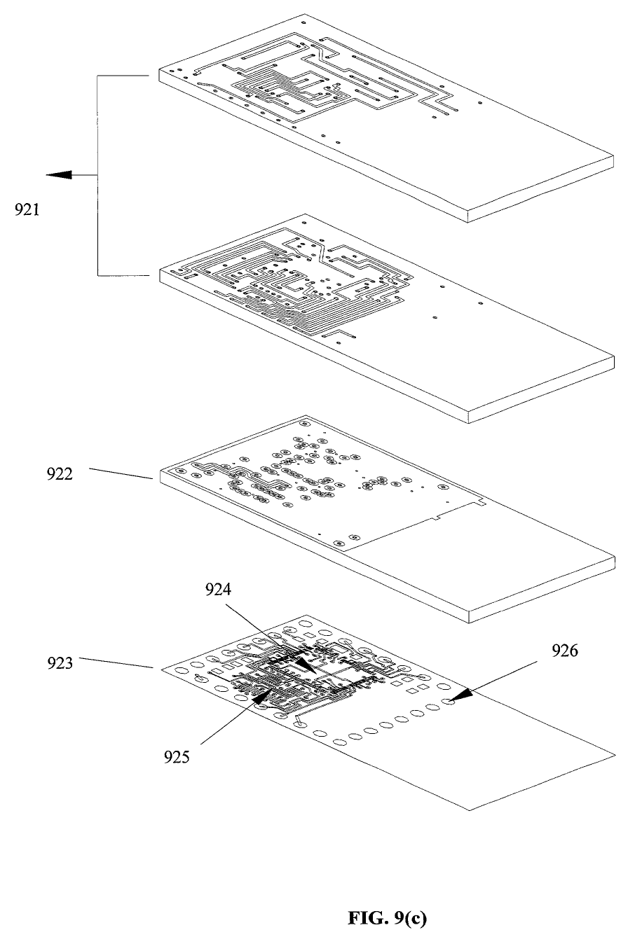

FIG. 9 shows an example of a miniaturized bluetooth wireless communication module that comprises multiple metal layers and ceramic substrates integrated according to the method of this invention. The module has sixteen layers of substrates and both top and bottom surfaces have circuit devices installed thereon. Integrated circuit devices are mounted directly on the top and bottom surfaces of the module using flip-chip packaging technology to save space.

As shown in FIG. 9(a), the top surface device area 901 has a radio frequency integrated circuit device 905 mounted using flip-chip technology, a switching diode device 906, a crystal oscillator 907 and a transistor 908. There are fifteen internal layers of metal. The first two metal layers 902 are connection layers for signal connection paths and DC power supply lines. Filled vias are provided for connecting to the devices on the top surface and the passive devices below the connection layers. The third metal layer 903 is a shielding ground plane. The fourth and fifth metal layers 904 are used to integrate high frequency isolation or short circuits. The sixth metal layer shown in FIG. 9(b) is another shielding ground plane.

The seventh to eleventh metal layers and associated ceramic substrates 911 are high frequency passive device integration layers that include two embedded baluns 913, one embedded high frequency filter 914 and an embedded antenna 912. Two shielding ground planes 916 and 917 are provided on the sixth layer and the twelfth layer respectively. Each device is isolated with filled vias connected to ground. The thirteenth and fourteenth layers 921 shown in FIG. 9(c) integrate the baseband signal connection. The fifteenth layer 922 is for baseband circuit grounding and part of the DC power supply lines. In addition to some connection lines and the baseband integrated circuit device 924 and the flash memory module 925 mounted using flip-chip technology, input and output contacts 926 of ball grid array type (BGA) are formed on the bottom surface 923 around the periphery of the circuit module to make the circuit module usable as a standard modularized device.

The design and integration method described above provides a technique for integrating integrated circuit devices and required passive devices into a multi-layer circuit module for a modern circuit system such as a wireless communication system. The result is a miniaturized and highly integrated wireless communication circuit module. A miniaturized sub-module required in the modern communication systems can also be designed and developed with the technique of this invention and integrated as a miniaturized circuit system without adding complicated peripheral circuits externally.

For a simpler communication system, the whole system circuit can be integrated in a small space with the method of the present invention. By means of standard input and output contacts, the miniaturized system can further be integrated in a product directly to add or provide additional function for the product. The design and integration method of this invention greatly reduces development cost and manufacturing time of a product. It is especially valuable to the development of light and compact communication devices with multiple functions.

According to the present invention, the multi-layer circuit module comprises a plurality of ceramic substrates. Active integrated circuit devices are mounted on one or both of the top and bottom surfaces of the circuit module. Because the ceramic substrates of this invention have sufficiently high Q-factor for the frequency band used in current wireless communication, passive devices can be fabricated and embedded directly in the multiple ceramic substrates to reduce the number of devices on the top and bottom surfaces. The size of the multi-layer circuit module is thus greatly reduced.

In the design method of the present invention, after each integration region is defined, passive devices can be designed in their integration regions under the constraint of the allowable layers. Filled vias are formed to provide connection between different layers. Shielding ground planes are used to effectively isolate the devices. The ceramic substrates have a low thermal expansion coefficient that makes the integration with other non-packaged integrated circuit devices very easy.

The above description refers to the preferred embodiments of the invention in which a basic passive device integration region comprises separate capacitor layers, resistor layers and inductor layers. However, if the circuit module does not require many basic passive devices, different passive devices may also be mixed in same layers to reduce the number of layers and the size of the circuit module. For example, capacitor layers may be formed with resisters or inductors. Resistor layers may be formed with capacitors or inductors, and inductor layers may be formed with resistors or capacitors. Similarly, the order of the basic passive device layers in the basic passive device integration region may be modified to meet other requirements in the circuit module. Under these circumstances, the performance may be compromised.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

Whis is claimed is:

1. A multi-layer circuit module, comprising:
a plurality of substrate layers and metal layers being divided into a plurality of integration regions including at least an inter-connection integration region, at least a basic passive device integration region and at least a high frequency passive device integration region;
a plurality of circuit devices mounted on at least one of top and bottom surfaces of said circuit module;
wherein said inter-connection integration region comprises at least one connection layer for circuit connection between said plurality of circuit devices, said basic passive device integration region comprises at least one basic passive device layer, and said high frequency passive device integration region comprises high frequency passive devices.

2. The multi-layer circuit module as claimed in claim 1, wherein said basic passive device integration region comprises at least one capacitor layer.

3. The multi-layer circuit module as claimed in claim 2, wherein said basic passive device integration region comprises a stacked capacitor fabricated on said at least one capacitor layer.

4. The multi-layer circuit module as claimed in claim 2, wherein said basic passive device integration region comprises a printed capacitor fabricated on said at least one capacitor layer.

5. The multi-layer circuit module as claimed in claim 2, wherein said basic passive device integration region comprises at least a resistor or inductor fabricated on said at least one capacitor layer.

6. The multi-layer circuit module as claimed in claim 1, wherein said basic passive device integration region comprises at least one resister layer.

7. The multi-layer circuit module as claimed in claim 6, wherein said basic passive device integration region comprises at least a capacitor or inductor fabricated on said at least one resistor layer.

8. The multi-layer circuit module as claimed in claim 1, wherein said basic passive device integration region comprises at least one inductor layer.

9. The multi-layer circuit module as claimed in claim 8, wherein said basic passive device integration region comprises a spiral line on said at least one inductor layer for forming an inductor.

10. The multi-layer circuit module as claimed in claim 8, wherein said basic passive device integration region comprises a transmission line on said at least one inductor layer for forming a high frequency short or isolation circuit on said at least one inductor layer.

11. The multi-layer circuit module as claimed in claim 8, wherein said basic passive device integration region comprises at least a resistor or capacitor fabricated on said at least one inductor layer.

12. The multi-layer circuit module as claimed in claim 1, wherein said high frequency passive device integration region comprises a high frequency filter.

13. The multi-layer circuit module as claimed in claim 1, wherein said high frequency passive device integration region comprises a high frequency coupler.

14. The multi-layer circuit module as claimed in claim 1, wherein said high frequency passive device integration region comprises high frequency baluns.

15. The multi-layer circuit module as claimed in claim 1, wherein said high frequency passive device integration region comprises an antenna.

16. The multi-layer circuit module as claimed in claim 1, wherein each of said plurality of integration regions has at least one shielding ground plane for shielding and isolating devices formed therein.

17. The multi-layer circuit module as claimed in claim 1, wherein said connection layer has at least one shielding ground plane for shielding and isolating circuit connection paths formed therein.

18. The multi-layer circuit module as claimed in claim 1, wherein said basic passive device layer has at least one shielding ground plane for shielding and isolating basic passive devices formed therein.

19. The multi-layer circuit module as claimed in claim 1, wherein devices in different integration regions or different layers are connected by filled vias.

20. The multi-layer circuit module as claimed in claim 1, wherein said plurality of substrate layers comprise ceramic substrates.

21. The multi-layer circuit module as claimed in claim 1, wherein said inter-connection integration region is located adjacent to said top or bottom surface on which circuit devices are mounted.

22. The multi-layer circuit module as claimed in claim 21, wherein said basic passive device integration region is located adjacent to said inter-connection integration region, said basic passive device integration region having capacitor layers adjacent to said inter-connection integration region and resistor layers next to said capacitor layers.

23. The multi-layer circuit module as claimed in claim 22, wherein said basic passive device integration region further comprises inductor layers following said resistor layers.

24. The multi-layer circuit module as claimed in claim 22, wherein only said top surface of said circuit module has circuit devices mounted thereon, said high frequency passive device integration region is formed next to said resistor layers, and inductor layers are formed following said high frequency passive device integration region.

25. The multi-layer circuit module as claimed in claim 1, wherein said inter-connection integration region is located next to a shielding ground plane adjacent to said top or bottom surface on which circuit devices are mounted.

26. The multi-layer circuit module as claimed in claim 1, wherein both top and bottom surfaces of said circuit module have circuit devices mounted thereon, and said high frequency passive device integration region comprises middle layers of said plurality of substrate layers and metal layers.

27. The multi-layer circuit module as claimed in claim 26, wherein basic passive device integration regions are formed on both sides of said high frequency passive device integration region.

28. The multi-layer circuit module as claimed in claim 27, wherein each of said top and bottom surfaces has an adjacent inter-connection integration region next to a basic passive device integration region adjacent to said high frequency passive device integration region.

29. A method of manufacturing a multi-layer circuit module, comprising the steps of:
a. dividing said circuit module into a plurality of integration regions including at least an inter-connection integration region, at least a basic passive device integration region and at least a high frequency passive device integration region;
b. forming at least one connection layer in said inter-connection integration region for circuit connection between a plurality of circuit devices;
c. forming at least a basic passive device layer in said basic passive integration region;
d. forming a plurality of high frequency passive devices in said high frequency passive device integration region; and
e. mounting a plurality of circuit devices on at least one of top and bottom surfaces of said circuit module.

30. The method of manufacturing a multi-layer circuit module as claimed in claim 29, wherein at least one capacitor layer is formed in said basic passive device integration region.

31. The method of manufacturing a multi-layer circuit module as claimed in claim 30, wherein a stacked capacitor is fabricated on said at least one capacitor layer.

32. The method of manufacturing a multi-layer circuit module as claimed in claim 30, wherein a printed capacitor is fabricated on said at least one capacitor layer.

33. The method of manufacturing a multi-layer circuit module as claimed in claim 30, wherein at least a resistor or inductor is fabricated on said at least one capacitor layer.

34. The method of manufacturing a multi-layer circuit module as claimed in claim 29, wherein at least one resistor layer is formed in said basic passive device integration region.

35. The method of manufacturing a multi-layer circuit module as claimed in claim 34, wherein at least a capacitor or inductor is fabricated on said at least one resistor layer.

36. The method of manufacturing a multi-layer circuit module as claimed in claim 29, wherein at least one inductor layer is formed in said basic passive device integration region.

37. The method of manufacturing a multi-layer circuit module as claimed in claim 36, wherein a spiral line is fabricated on said at least one inductor layer for forming an inductor.

38. The method of manufacturing a multi-layer circuit module as claimed in claim 36, wherein a transmission line is fabricated on said at least one inductor layer for forming a high frequency short or isolation circuit.

39. The method of manufacturing a multi-layer circuit module as claimed in claim 36, wherein at least a resistor or capacitor is fabricated on said at least one inductor layer.

40. The method of manufacturing a multi-layer circuit module as claimed in claim 29, wherein a high frequency filter is formed in said high frequency passive device integration region.

41. The method of manufacturing a multi-layer circuit module as claimed in claim 29, wherein a high frequency coupler is formed in said high frequency passive device integration region.

42. The method of manufacturing a multi-layer circuit module as claimed in claim 29, wherein baluns are formed in said high frequency passive device integration region.

43. The method of manufacturing a multi-layer circuit module as claimed in claim 29, wherein an antenna is formed in said high frequency passive device integration region.

44. The method of manufacturing a multi-layer circuit module as claimed in claim 29, wherein each of said plurality of integration regions has at least one shielding ground plane for shielding and isolating devices formed therein.

45. The method of manufacturing a multi-layer circuit module as claimed in claim 29, wherein said connection layer has at least one shielding ground plane for shielding and isolating circuit connection paths.

46. The method of manufacturing a multi-layer circuit module as claimed in claim 29, wherein said basic passive device layer has at least one shielding ground plane for shielding and isolating basic passive devices formed therein.

47. The method of manufacturing a multi-layer circuit module as claimed in claim 29, wherein devices in different integration regions or different layers are connected by filled vias.

48. The method of manufacturing a multi-layer circuit module as claimed in claim 29, wherein said circuit module comprises a plurality of ceramic substrate layers and metal layers divided into said plurality of integration regions.

49. The method of manufacturing a multi-layer circuit module as claimed in claim 29, wherein said inter-connection integration region is formed adjacent to said top or bottom surface on which circuit devices are mounted.

50. The method of manufacturing a multi-layer circuit module as claimed in claim 49, wherein said basic passive device integration region is formed adjacent to said interconnection integration region, said basic passive device integration region having capacitor layers adjacent to said inter-connection integration region and resistor layers next to said capacitor layers.

51. The method of manufacturing a multi-layer circuit module as claimed in claim 50, wherein said basic passive device integration region further comprises inductor layers following said resistor layers.

52. The method of manufacturing a multi-layer circuit module as claimed in claim 50, wherein only said top surface of said circuit module has circuit devices mounted thereon, said high frequency passive device integration region is formed next to said resistor layers, and inductor layers are formed following said high frequency passive device integration region.

53. The method of manufacturing a multi-layer circuit module as claimed in claim 29, wherein said inter-connection integration region is formed next to a shielding ground plane adjacent to said top or bottom surface on which circuit devices are mounted.

54. The method of manufacturing a multi-layer circuit module as claimed in claim 29, wherein a plurality of circuit devices are mounted on both top and bottom surfaces of said circuit module, and said high frequency passive device integration region is formed by middle layers of a plurality of substrate layers and metal layers of said circuit module.

55. The method of manufacturing a multi-layer circuit module as claimed in claim 54, wherein basic passive device integration regions are formed on both sides of said high frequency passive device integration region.

56. The method of manufacturing a multi-layer circuit module as claimed in claim 55, wherein each of said top and bottom surfaces has an adjacent inter-connection integration region next to a basic passive device integration region adjacent to said high frequency passive device integration region.
